(19) United States
(12) Patent Application Publication
(10) Pub. No.: US 2005/0126707 A1
(43) Pub. Date: Jun. 16, 2005

(54) Manufacture having double sided features in a metal-containing web and manufacture and method for forming same in a liquid-based etch process

(76) Inventors: Laurence M.C. Lai, Mississauga (CA); Anthony Russell, Rockwood (CA); Michael J. Shaw, Thornhill (CA)

Correspondence Address: WOMBLE CARLYLE SANDRIDGE & RICE, PLLC, P.O. BOX 7037, ATLANTA, GA, 30357-0037, US

(21) Appl. No.: 11/047,962

(22) Filed: Feb. 1, 2005

Related U.S. Application Data
(62) Division of application No. 09/989,898, filed on Nov. 19, 2001, now Pat. No. 6,887,394.

(51) Int. Cl. H01L 21/306; B32B 3/00; B32B 15/00; B32B 15/04

(52) U.S. Cl. 156/345.11; 428/209; 428/457; 428/98

(57) ABSTRACT

To achieve a large thickness of conductive metal-containing material in a feature of a product unit processed with a liquid-based etch process, the desired thickness of material is apportioned to the two opposing surfaces of a substrate to create a two-part feature. Conventional features are made by identically patterning two same-thickness metal-containing layers and electrically connecting the resulting patterned parts in any suitable manner. However, features may also be made that do not have identical parts on opposite sides of the substrate, the two parts being electrically connected but differing in thickness, in shape, or both Moreover, having two metal-containing layers separated by an insulator is also useful for allowing different sections of the same feature or circuit to cross one another without shorting, or to overlap in whole or in part without shorting.

### BACKGROUND OF THE INVENTION

1. Field of the Invention

The present invention relates to forming features in a metal-containing web using liquid-based etch process, and more particularly to forming double sided features in a metal-containing web by a liquid-based etch process.

2. Description of the Related Art

Functional patterns formed into aluminum foil are used in a variety of products, including thin foil products such as microwave plates, trays and bowls, as well as thick foil products such as planar speakers, electronic circuitry surveillance products used for shoplifting prevention in retail environments, and flexible heaters, just to name a few. Common processes to form these products includes chemical milling or chemical etching of a metal-containing layer of a web. The metal-containing layer typically is a metal foil of aluminum or copper or, less commonly, silver having a desired thickness that is laminated to or otherwise formed on a suitable substrate. A desired pattern is formed on the surface of the metal foil with a etch resistant protective coating, typically by using Gravure printing or silk screen printing. The web with the printed metal foil is introduced to an etching solution, whereupon the metal foil in the open areas of the pattern is etched away to leave behind the desired protected features of the pattern. The etching bath can be acidic or basic in nature, depending on the type of metal. The foil can be of different thickness, depending on the intended function of the desired product.

A liquid-based etch process for fabricating planar electrical circuits that is especially adapted for use in electronic security systems is described in U.S. Pat. No. 3,913,219, issued Oct. 21, 1975 to Lichtblau. The process begins with an electrically insulating substrate that has conductive foil directly bonded on each opposite surface. The thickness of the substrate is maintained to an accurate tolerance commensurate with the intended resonant properties of a completed resonant tag circuit, which is formed by repetitive planar patterns on both conductive surfaces. In particular, the web emerging from the process has circuit patterns on one foil side, the thick foil side, each of which contains two inductors and respective first plates for two capacitors, and has circuit patterns on the other side, the thin foil side, each of which contains a fusible link and respective second plates for the two capacitors. The plates of the capacitors are separated by the substrate, the dielectric characteristics of which affect the value of the two capacitors. The functions performed by the structures provided on the thick foil side, namely inductance and charge storage at one potential, are distinctly different than the functions performed by the structures provided on the thin foil side, namely fusible conductance and charge storage at another potential.

Continuous etching or milling processes are particularly advantageous when large amounts of patterned web is required because of the low cost per product unit relative to non-continuous processes. A particularly useful liquid-based continuous demetallizing process and apparatus are described in U.S. Pat. No. 5,340,436, which issued Aug. 23, 1994 to D. Gregory Beckett. Generally speaking, the apparatus has an elongate tank that holds a bath of aqueous etchant material. The web containing the metal layer to be etched initially is arranged in a roll. The web is taken off of the roll and guided into the bath at one end, guided either horizontally or sinusoidally through the bath, and removed from the bath and taken up on another roll at the opposing end of the bath The web is driven along its path by any suitable drive mechanism. An example of a drive mechanism is a combination of driven belts and roller elements. The web passes between these elements, which engage the web and drive it.

Planar speakers have been known for many years but have not achieved widespread commercial success because of the relatively high cost of manufacture of the diaphragm element. A schematic of an illustrative planar speaker diaphragm 100 is shown in FIG. 1, greatly simplified for purposes of explanation. FIG. 1 shows a conductive path 120 mounted on a thin insulating flexible substrate 110. An alternating audio current is established in the path 120 by an audio source 130. The alternating current flow establishes a varying magnetic field about the path 120 (not shown), which interacts with stable magnetic flux lines (indicated by the arcs with north indicated by “N” and south indicated by “S”) established typically by sets of permanent magnets (not shown) to cause the diaphragm to move up and down (indicated by the arrows marked “M”). The acceleration of the diaphragm 100 is a function of many variables, including the length, thickness and width of each trace in the conductive path as well as the number and spacing of the traces. The best conductive path includes a number of very thick but narrow traces of very specific design that are densely packed. Thick traces are desirable because they reduce resistance in lower frequency circuits, thereby allowing greater power density to be achieved. The diaphragm 100 typically is the most expensive component of the planar speaker to manufacture.

The continuous etch process of the '436 patent has commonly and successfully been used to make blanks for microwave plates, trays and bowls, but it is also useful in the large scale fabrication of items made from webs having thicker metal layers. Accordingly, it is desired to fabricate speaker diaphragms with thick metal traces using a continuous etch process to achieve low per unit cost but without sacrificing the quality of the traces in the conductive path.

### BRIEF SUMMARY OF THE INVENTION

While continuous etch processes such as the process of the '436 patent are useful in the fabrication of patterned product units on webs, they can lead to sidewall profiles that are not optimal for some applications such as speaker diaphragms that include thick conductive traces. The reason is due to the highly exothermic nature of such etch processes. The processing of a thick metal-containing layer on a web requires a longer dwell time of the web in the etchant liquid. The increased dwell time results in greater localized heating. Both the resist and upper sidewalls of the etched features are thereby subjected to increased chemical and thermal abuse, which severely constrains resist material selection and causes degraded sidewall quality, resulting in reduced effective cross-section as well as reduced packing density due to increased effective spacing. Even continuous spray etching processes such as the process of the '219 patent can under certain circumstances lead to sidewall profiles that are not optimal for some applications.

These and other disadvantages sometimes encountered in using a liquid-based etch process in the fabrication of patterned webs that include thick conductive traces are overcome in the present invention, which in one embodiment is ______. !!

### BRIEF DESCRIPTION OF THE SEVERAL VIEWS OF THE DRAWINGS

FIG. 1 is a schematic drawing showing the principles behind operation of a planar speaker of the prior art.

FIG. 2 is a schematic representation of the movement of a web containing product units through a machine that performs a continuous etch.

FIG. 3 is a plan view of an illustrative trace design.

FIG. 4 is a cross-section view of a patterned resist layer from the trace design of FIG. 3, as formed on a thin metal layer of a web.

FIG. 5 is a cross-section view of ideal etched trace profiles from the web of FIG. 4.

FIGS. 6 is a cross-section view of practical etched trace profiles from the web of FIG. 4.

FIG. 7 is a cross-section view of a patterned resist layer from the trace design of FIG. 3, as formed on a thick metal layer of a web.

FIG. 8 is a cross-section view of ideal etched trace profiles from the web of FIG. 7.

FIGS. 9 is a cross-section view of practical etched trace profiles from the web of FIG. 7.

FIG. 10 is a cross-section view of two patterned resist layers as formed on separate metal layers on opposite sides of a web.

FIG. 11 is a cross-section view of practical etched trace profiles from the web of FIG. 10.

FIGS. 12-16 are cross-section views of various interconnection techniques for use on a planar speaker diaphragm

FIGS. 17 and 18 are schematic representations of respective sections of a circuit trace design for the metal layers on opposite sides of a web.

FIG. 19 is a schematic representation of the juxtaposed sections of FIGS. 16 and 17, and also shows a current path therethrough.

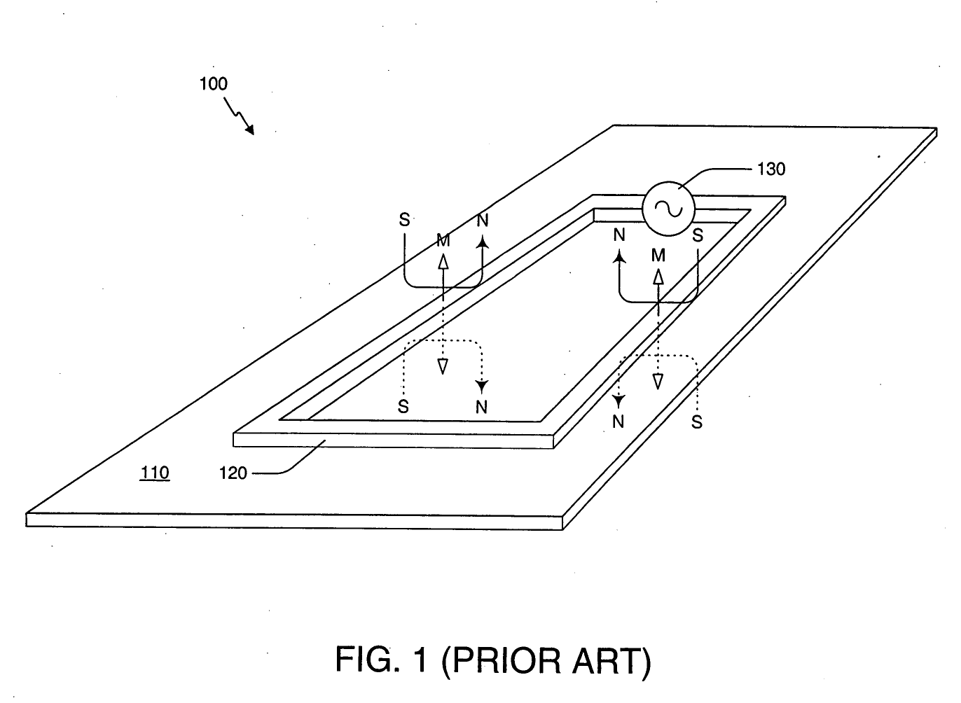

### DETAILED DESCRIPTION OF THE INVENTION, INCLUDING THE PREFERRED EMBODIMENT

Many useful products such as microwave plates, trays and bowls, planar speakers, electronic circuitry surveillance products, and flexible heaters are made from product units that contain one or more etched features. The features serve various well known functions in the final product, including shielding, localized heating, standing wave modification, and attenuation in microwave applications, magnetic motor action in planar speakers, heat generation in flexible heaters, and field disruption in electronic circuitry surveillance. The shape of a feature is influenced by its function, and ranges from patch-like to trace-like.

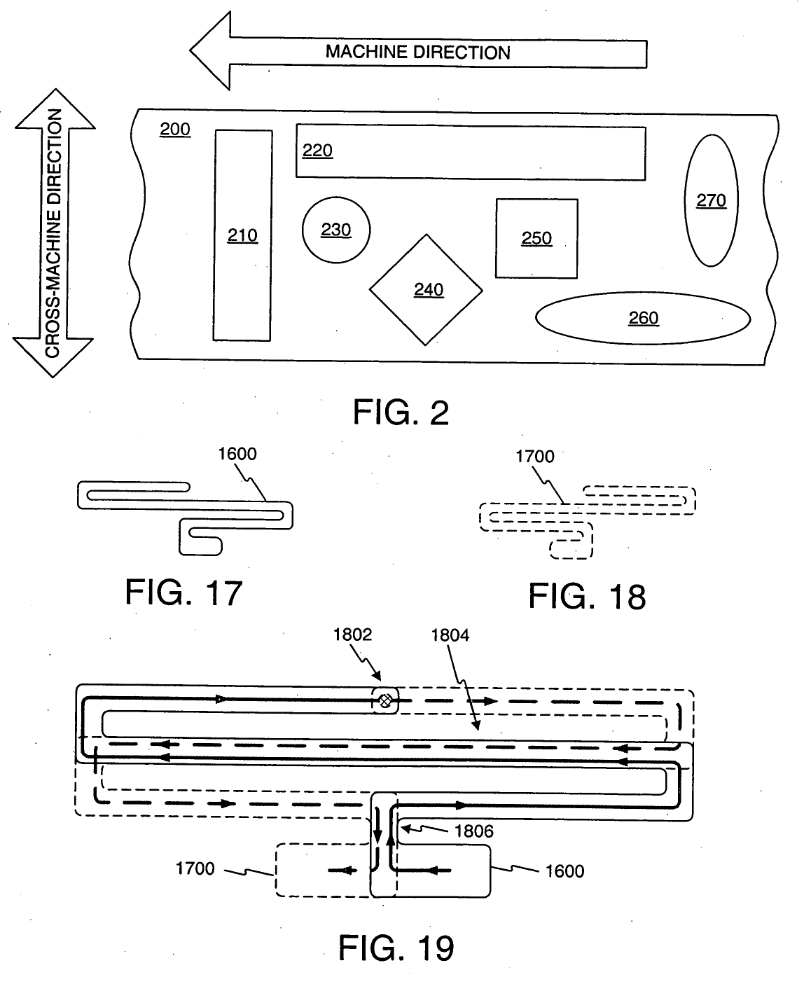

The product units and the feature or features within them can have a variety of different shapes. FIG. 2 is a schematic diagram of a section of a web 200 that contains a variety of product units 210, 220, 230, 240, 250, 260 and 270 of various shapes, sizes and configurations. Although a web typically contains just one or perhaps a few types of product units, FIG. 2 suggests the variety of different types of product units to which the techniques described herein may be applied. The web 200 is moved through the bath of a continuous etch process along its length, and indicated by the arrow marked “MACHINE DIRECTION.” The other direction is the “CROSS-MACHINE DIRECTION.” The rectangular product unit 210 is suggestive of a product unit that may have long sections of one or more features such as a trace or traces lying in a cross-machine direction. The rectangular product unit 220 is suggestive of a product unit that may have short sections of one or more features such as a trace or traces lying in a cross-machine direction. The circular product unit 230 is suggestive of a product unit that may have one or more circular features. The square product unit 240 is suggestive of a product unit that may have two opposing feature sections lying in a cross-machine direction. The square product unit 250 is suggestive of a product unit that may have four opposing feature sections lying in part in a cross-machine direction. The oval product unit 260 is suggestive of a product unit that may have short arcs lying in a cross-machine direction. The oval product unit 270 is suggestive of a product unit that may have long arcs lying in a cross-machine direction.

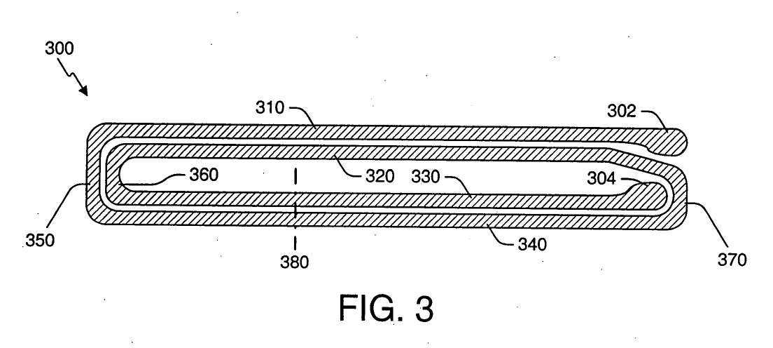

An illustrative type of thick feature useful in planar speakers, flexible heaters, and electronic surveillance circuitry is the trace. Such traces usually are very long and very narrow, and typically are also quite thick to reduce circuit resistance. Traces used in some applications such as planar speakers may be multiply-folded, for which rectangular product units such as 210 and 220 are especially suitable. FIG. 3 is an example of an original trace design for a planar speaker circuit, greatly simplified for purposes of clarity and explanation, which has a single long trace 300 folded three times which is set within a frame (not shown) in a manner well known in the art. The trace 300 terminates in bonding pads 302 and 304 in a manner well known in the art. Long sections 310, 320, 330 and 340 of the trace 300 preferably are oriented in a longitudinal direction relative to the web, or in the machine direction relative to the motion of the web through the continuous demetallizing apparatus (FIG. 2). These long sections are interconnected by relatively short sections 350, 360 and 370 that preferably are oriented in a latitudinal direction relative to the web, or in a cross-machine direction relative to the motion of the web through the continuous demetallizing apparatus (FIG. 2).

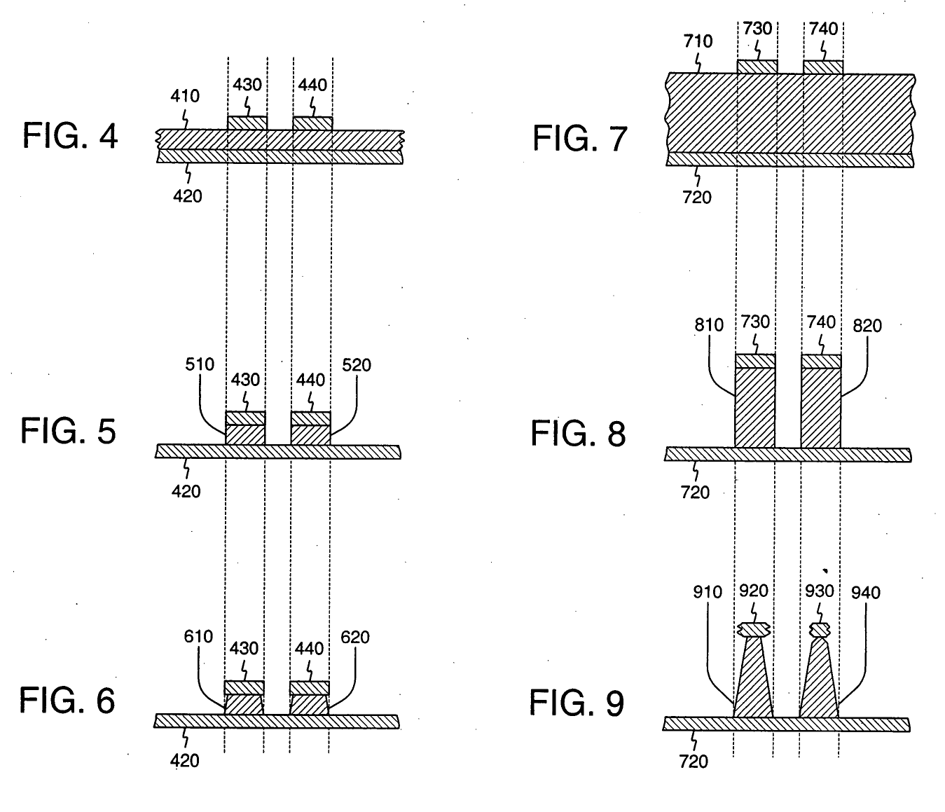

The trace design 300 of FIG. 3 is used to form a resist pattern on a web. FIG. 4 shows an illustrative web having a metal foil layer 410 upon but not necessarily in direct contact with a substrate 420. Typically, the metal foil layer 410 is bonded to the substrate by an adhesive layer (not shown), and other intervening layers (not shown) may be used if desired. Illustrative resist sections 430 and 440, which for example correspond to a cross section of the trace 300 as defined by a plane 380 (FIG. 3), are upon but not necessarily in contact with the foil layer 410. Typically, the resist is directly applied to the foil layer 410.

An ideal trace cross-section is shown in FIG. 5. The trace sections 510 and 520 are well formed, having a full cross-section and preserving a high packing density in that the sidewalls are closely spaced. The resist sections 430 and 440 are perfectly preserved throughout the etch process.

A simplified practical trace cross-section is shown in FIG. 6. The trace sections 610 and 620 exhibit some minor narrowing, which progressively increases toward the top of the trace sections 610 and 620 due to overetch caused by progressively greater exposure to hot etchant. However, the overetch is of little consequence, since nearly the full cross-section is achieved and the close spacing of the sidewalls is essentially preserved. The resist sections 430 and 440 may suffer some degradation (not shown) from the etch process and some undercutting occurs, but the degradation is minor and the resist sections 430 and 440 generally remain intact throughout the etch process, if and until they are intentionally removed.

The results are quite different when the trace design 300 of FIG. 3 is used to form a resist pattern on a web having a thick metal-containing layer. FIG. 7 shows an illustrative web having a thick metal foil layer 710 upon a substrate 720. Illustrative resist sections 730 and 740, which for example correspond to a cross section of the trace 300 as defined by a plane 380 (FIG. 3), are upon the thick foil layer 710.

An ideal trace cross-section is shown in FIG. 8. The trace sections 810 and 820 are well formed, having a full cross-section and preserving a high packing density in that the sidewalls are closely spaced. The resist sections 730 and 740 are perfectly preserved throughout the etch process.

A simplified practical trace cross-section is shown in FIG. 9. The trace sections 910 and 920 exhibit severe narrowing, which progressively increases toward the top of the trace sections 910 and 920 due to sustained overetching caused by progressively greater exposure to hot etchant. The cross-section area of the trace sections 910 and 920 is greatly diminished relative to the ideal cross-sections 810 and 820 (FIG. 8), and the close spacing of the sidewalls shown in FIG. 8 is lost, resulting in a decrease in the effective packing density. The resist sections 730 and 740 (FIG. 7) suffer considerable degradation due to prolonged exposure to the etchant, which may leave some sections of the resist damaged but essentially intact (see, e.g., resist section 920) but may result in other sections suffering edge breakage and severe undercutting (see, e.g., resist section 930).

As is apparent from a comparison of FIG. 6 and FIG. 9, the progressive narrowing of the etched metal-containing feature sections places a limitation on the width vs. thickness ratio that can be achieved using a liquid-based process. Once this limit is exceeded, the resist pattern section is completely undercut and lifts off of the etched metal-containing feature section, thereby allowing the etched metal-containing feature to be further etched from the top as well as the sidewalls.

While feature degradation can be tolerated for some types of product units, other types of product units require a high degree of fidelity between the original feature design and the etched feature appearing in the product unit. This is particular true of the circuit in a speaker diaphragm, for example, which typically has one very lengthy multiply-folded trace—but which may have more than one trace if desired—that is designed to have a specific impedance and many densely packed sections to induce a specifically shaped strong magnetic field upon the application of a drive current. A significant deviation from the original trace design in any part of the etched trace can cause the speaker diaphragm to be out of specification, thereby decreasing the process yield and increasing manufacturing cost. Moreover, a significant deviation from the original trace design in any part of the etched trace can cause the speaker diaphragm to fail after installation in the product, thereby leading to poor product reliability and higher after-sale warranty expenses.

To achieve a large thickness of conductive metal-containing material in a feature of a product unit processed with a liquid-based etch process, the desired thickness of material for the feature is apportioned to the two opposing surfaces of an insulating substrate to create a two-part feature, each part of which performs the identical function. Conventional features, which are generally symmetrical about a plane parallel to the product unit, are made by similarly patterning the feature, and preferably identically patterning the feature, in a mirror image on two opposing same-thickness metal-containing layers, and electrically connecting the resulting mirror image parts in any suitable manner. This technique is useful for fabricating planar speaker circuit traces, for example. However, two part features may also be made that do not have identical mirror image parts on opposite sides of the substrate, the two parts being electrically connected and collectively performing the same function as the one part feature but having different thickness, or having shape variations that do not affect the overall feature function, or having both different thickness and shape variations that do not affect the overall feature function.

The apportionment may be equal or unequal, as desired. However, if unequal apportionment is used, the pattern that define feature parts made from the thinner metal-containing layer is adjusted to accommodate a degree of overetch that is experienced by the thinner metal-containing layer to allow complete removal of material from the thicker metal-containing layer.

In addition to having one or more features apportioned among the two opposing surfaces of an insulating substrate, one or more other features may be fabricated on one or the other side of the insulating substrate. For example, a speaker system may be optimized for different bandwidths by having a separate sub-woofer along with a planar speaker with a diaphragm having a main range circuit and a tweeter circuit. In one possible arrangement, the main range circuit is apportioned among the two sides of the diaphragm, while the tweeter circuit is fabricated on one side only or while different tweeter circuits are fabricated on one or both sides. The tweeter modulates a small section of the diaphragm so that its performance is not compromised by the mass of the main range circuit. As another example, all or parts of the inductors of an electronic circuit surveillance device are apportioned among the two sides of the substrate, while the fusible link or other variable impedance element is fabricated on one side and the respective plates of the capacitors are fabricated on the opposing sides.

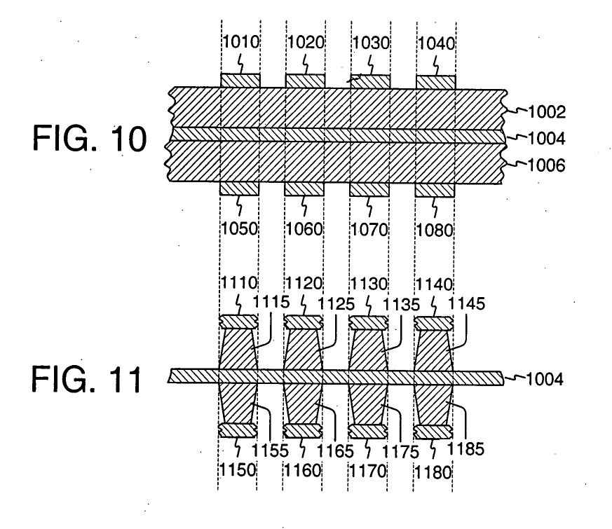

FIG. 10 shows an illustrative web having a substrate 1004. Metal foil layers 1002 and 1006 are upon the opposing surfaces of the substrate 1004. The metal foil layers 1002 and 1006 are each about half the desired foil thickness, and together add to the desired foil thickness. Illustrative resist sections 1010, 1020, 1030 and 1040 are upon the surface of the metal foil layer 1002. Illustrative resist sections 1050, 1060, 1070 and 1080 are upon the surface of the metal foil layer 1006. The resist sections 1010 and 1050 define different parts of the same feature section, the feature illustratively being a folded trace as may be used in a planar speaker diaphragm, for example. Similarly, the resist sections 1020 and 1060 define different parts of the same feature section, the resist sections 1030 and 1070 define different parts of the same feature section, and the resist sections 1040 and 1080 define different parts of the same feature section. Illustratively, the various feature sections so defined are all parts of the same folded trace.

When etched by a liquid-based process, the web of FIG. 10 appears as shown in FIG. 11. While the half-thickness trace sections 1015, 1025, 1035, 1045, 1055, 1065, 1075 and 1085 exhibit some progressive narrowing with increased distance from the substrate 1004, the effect on the cross-section area of these trace sections is significantly less than trace sections made from a full foil thickness. Similarly, although some of the close spacing of the sidewalls is lost relative to the ideal profile, the effect is significantly less than occurs between trace sections made from a full foil thickness. Hence, packing density is improved over the full foil thickness approach While the resist sections 1010, 1020, 1030, 1040, 1050, 1060, 1070 and 1080 suffer some degradation due to some degree of prolonged exposure to the etchant, the degradation is significantly less than occurs when trace sections are made from a full foil thickness.

Examples of a particularly effective and economical continuous demetallizing process and of machinery useful for practicing the process are described in U.S. Pat. No. 5,340,436, which is entitled “Demetallizing Procedure” and issued Aug. 23, 1994 to D. Gregory Beckett, which is hereby incorporated herein in its entirety by reference. The '436 patent involves the selective demetallizing of an etchable metal layer supported on a layer of suitable material or a self-supporting etchable metal layer. In one embodiment, a web of polymeric material bearing the etchable metal layer, illustratively aluminum, has a pattern of etch-resistant material applied to it. Then, the web is immersed in and passed through a bath of aqueous etchant, illustratively an aqueous sodium hydroxide base solution at an elevated temperature, for a time at least sufficient to remove the etchable metal from non-protected areas of the web. In another embodiment, a web of unsupported etchable metal, illustratively aluminum, has a pattern of etch-resistant material applied to both sides, in register. Then, the web is immersed in and passed through a bath of aqueous etchant, illustratively an aqueous sodium hydroxide base solution at an elevated temperature, for a time at least sufficient to remove the etchable metal from non-protected areas of the web, thereby forming orifices completely through the web. The demetallized web is washed and dried.

An illustrative metal-containing web that has etch-resistant resist patterns for forming various functional and perhaps other features when processed in the continuous etch processes of the '436 patent and others like it is now described in detail. The initial web laminate is formed by mounting a metal foil or a metal-containing foil onto both opposing surfaces of a suitable substrate, such as polyester or polymeric material. While any suitable method may be used, a suitable well known process for aluminum, for example, involves laminating aluminum foil to a layer of polyester or polymeric material using a dry bond adhesive, in a manner well known in the art. The combined foil thickness for use in continuous etch processes and equipment like that described in the '436 patent is generally determined by the capabilities of the foil manufacturer and the limitations of the web handling components in handling rolls of web layer materials and the finished web. Presently, these factors establish a combined foil thickness in the range of from about 1 micron to about 75 microns, although combined foil thickness in excess thereof may be use in the future. The actual combined foil thickness used in the web depends on the application. Illustratively, for microwave applications, two aluminum foil layers of about 1 micron to about 15 microns combined thickness and greater are mounted to the opposing surfaces of a PET polyester film of about 48 gauge. Illustratively, for planar speaker diaphragms, two aluminum foil layers of about 5 microns to about 50 microns thickness and greater are mounted to the opposing surfaces of a PEN film of about 48 gauge. However, greater combine thickness such as 70 microns or even 100 microns may be used for large planar speakers. Illustratively, for electronic article surveillance products, two aluminum foil layers of from about 5 microns to about 70 microns combined thickness and greater are mounted to the opposing surfaces of a PET polyester film of about 48 gauge.

Next, patterns of etch-resistant material such as, for example, resin are printed by, for example, using Gravure printing onto both of the foil sides of the web in register with one another to form protective etch masks, in a manner well known in the art. A suitable etch-resistant material for a sodium hydroxide base solution etchant is a vinyl chloride co-polymer resin. Other techniques for forming a pattern of etch-resistant material include spraying and the use of photoresist material. The thickness of the etch-resistant layer is determined by the strength and temperature of the etchant along with the time over which the etch-resistant material is exposed to the etchant, in a manner well known in the art. The protective coatings are dried and the web either is rolled onto a spindle for later etching in a continuous demetallizing process, or is directly introduced into the continuous demetallizing process. While the particular size of the web depends on the particular equipment used in the process, a typical web size for the process and equipment described in the '436 patent is from about 31 to about 36 inches wide and about 5000 feet to about 10,000 feet long, rolled onto a spindle in a maimer well known in the art.

Next, the web is etched in the continuous demetallizing process, in a manner well known in the art.

Subsequent steps depend on the product being made. Where the product is for microwave cooking applications, illustratively the web is laminated using a wet bond adhesive to a paper product having any suitable thickness, typically from about 20 pound paper to about 24 point paperboard, and various product units which include one or more of the functional features are cut out using any suitable technique such as a die cutting machine or robotic cutting, as are well known in the art. Microwave cooking articles are available from a variety of manufacturers, including Graphic Packaging Corporation of Golden, Colo. Where the product is for planar speaker applications, the functional features include circuit elements, and various product units which includes respective circuits formed from one or more of the circuit elements are cut out using any suitable technique such as a die cutting machine or robotic cutting, as are well known in the art, and suitably packaged into a speaker housing. Planar speaker drivers are available from a variety of manufacturers, including American Technology Corporation of San Diego, Calif. Where the product is for electronic article surveillance products, the functional features include circuit elements, and various product units which includes respective circuits formed from one or more of the circuit elements are cut out using any suitable technique such as a die cutting machine or robotic cutting, as are well known in the art, and suitably packaged. The finished products tend to be about one to about one and a half inch square, but other sizes and shapes are also used. Electronic article surveillance products are available from a variety of manufacturers, including Checkpoint Systems, Inc. of Thorofare, N.J.

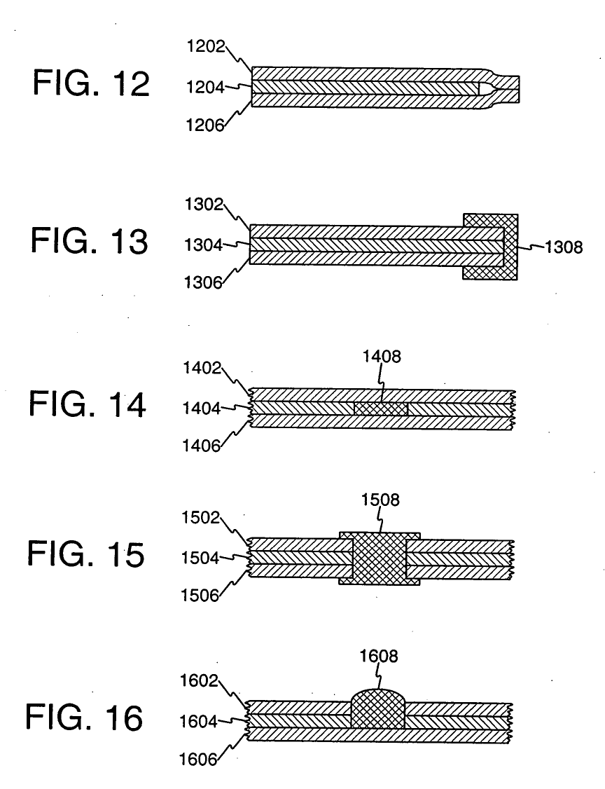

Feature parts on opposite sides of a substrate may be interconnected in any desired manner. For instance, FIG. 12 shows an illustrative technique wherein foil feature parts 1202 and 1206 on opposite sides of the substrate 1204 extend off the edge of the substrate 1204 and are crimped, bonded with a conductive adhesive, or otherwise fastened to one another. FIG. 13 shows an illustrative technique wherein a conductive strip or clip 1308 is applied at the edge of a substrate 1304 to establish a conductive path between conductive feature parts 1302 and 1306. FIG. 14 shows an illustrative technique wherein a conductive paste 1408 fills a via through a substrate 1404 to establish a conductive path between conductive feature parts 1402 and 1406. FIG. 15 shows an illustrative technique wherein a conductive rivet 1508 or other such fastener is placed in a via through a substrate 1504 and. conductive feature parts 1502 and 1506 to establish a conductive path between the conductive feature parts 1502 and 1506. FIG. 16 shows an illustrative technique wherein a weld or solder joint is made through a substrate 1604 to establish a conductive path between conductive feature parts 1602 and 1606. Leads may also be extended from the two sides of the planar speaker diaphragm and interconnected off of the diaphragm, if desired.

The ability to place features and feature parts on opposite sides of a substrate affords enormous flexibility in feature design. FIG. 19 is an example of a circuit trace formed by etching a trace section 1600 (FIG. 17) on one side of a substrate, and a trace section 1700 (FIG. 18) on another side of the substrate. The trace sections 1600 and 1700 are interconnected in any suitable manner where they overlap through a small zone 1802. A strong magnetic field is formed throughout a lengthy elongated zone 1804 where the current flows through the two trace sections 1600 and 1700 are in the same direction. Magnetic field formation is minimized throughout an short elongated zone 1806 where the current flows through the two trace sections 1600 and 1700 are in opposite direction. Traces may also be designed that cross one another at right angles (not shown) to minimize interaction between magnetic fields.

It will be appreciated that the type of metal or metal-containing material and the substrates described herein are illustrative, as are the various thickness, widths, lengths, and so forth. The planar speaker diaphragm and the electronic circuit surveillance device described herein also are illustrative, as the techniques described herein are applicable to other applications, and are particularly advantageous when applied to other applications that involve the use of thick metal foil such as, for example, flexible heaters. The choice as to material and thickness depends on the application and the temperatures encountered in the demetallizing process. For example, polyethylene terepthalate (“ET”) is suitable for many applications over a wide range of process temperatures, while Kaladex™ polyethylene naphthalate (“EN”) and Kapton™ polyimide, which are available from E.I. du Dupont de Nemours and Company of Wilmington, Del., are especially suitable where metal-containing webs are processed at elevated bath temperatures.

While the techniques described herein are especially useful for forming product units from a web whose metal-contaig layer is aluminum or copper foil, the techniques described herein may also be used to form product units from a web whose metal-containing layer is made in other ways such as, for example, by vapor deposition of metal. The metal itself may be a any metal or any alloy, or may contain added impurities to achieve certain desired electrical properties such as a particular resistivity or certain desired mechanical or chemical properties, or may be coated by an oxide of the metal formed by interaction of the metal with oxygen. Moreover, the metal-containing layer may be a composite structure made of multiple layers, which may include such material as metal foil or vapor deposited metal or both, and may even include non-metallic materials. The metal-containing layer may also be a non-metallic material such as polysilicon into which metal impurities have been introduced by doping or other suitable process to achieve a desired degree of electrical conductivity.

It will be appreciated that the specific materials and the thickness and other dimensions are illustrative, and will vary considerably in practice depending on a many factors such as the particular feature design, the thickness of the metal-containing layer, the desired results, and the specific application.

The scope of the invention is set forth in the following claims. The description of the various embodiments set forth herein is illustrative of the invention and is not intended to limit the scope thereof. Variations and modifications of the embodiments disclosed herein will become apparent to those of ordinary skill in the art upon reading this patent document, and alternatives to and equivalents of the various elements of the embodiments will be known to those of ordinary skill in the art. These and other variations and modifications of the embodiments disclosed herein may be made without departing from the scope and spirit of the invention as set forth in the following claims.

1. A metal-containing web for use in a liquid-based etch process to make product units, comprising:
an elongated substrate having first and second opposing surfaces;
a first metal-containing layer disposed upon the first surface of the substrate;
a first etch-resistant layer disposed upon the first metal-containing layer, the first etch-resistant layer having a first pattern substantially defining at least a part of at least a first functional feature of the product unit;
a second metal-containing layer disposed upon the second surface of the substrate; and
a second etch-resistant layer disposed upon the second metal-containing layer in register with the first etch-resistant layer, the second etch-resistant layer having a second pattern substantially defining at least the first functional feature part.

2. The web of claim 1 wherein the first and second metal-containing layers are of equal thickness.

3. The web of claim 1 wherein the first and second metal-containing layers are of unequal thickness.

4. The web of claim 1 wherein the first and second patterns comprise mirror image areas at least where the first functional feature part is defined.

5. The web of claim 1 wherein the first pattern further defines a second functional feature of the product unit.

6. The web of claim 1 wherein:
the first pattern further substantially defines at least part of a second functional feature of the product unit; and
the second pattern further substantially defines the second functional feature part.

7. The web of claim 1 wherein the first and second metal-containing layers comprise aluminum foil.

8. The web of claim 1 wherein the first and second metal-containing layers comprise deposited aluminum-containing material.

9. The web of claim 1 wherein the first and second metal-containing layer comprise copper foil.

10. A metal-containing web for use in a liquid-based etch process to make a planar speaker diaphragm, the planar speaker diaphragm having at least one circuit trace having functional areas for interacting with an externally imposed magnetic field, comprising:
an elongated substrate having first and second opposing surfaces;
a first metal foil layer disposed upon the first surface of the substrate;
a first etch-resistant layer disposed upon the first metal foil layer, the first etch-resistant layer having a first pattern defining at least the functional areas of the circuit trace;
a second metal foil layer disposed upon the second surface of the substrate; and
a second etch-resistant layer disposed upon the second metal foil layer in register with the first etch-resistant layer, the second etch-resistant layer having a second pattern defining at least the functional areas of the circuit trace.

11. The web of claim 10 wherein the first and second patterns comprise mirror image areas at least where the functional areas of the circuit trace are defined.

12. The web of claim 11 wherein the first and second metal foil layers are of equal thickness.

13. The web of claim 12 wherein:
the first pattern further defines the circuit trace in entirety; and
the second pattern further defines the circuit trace in entirety.

14. The web of claim 10 wherein:
the first pattern further defines the circuit trace in entirety;
the second pattern further defines the circuit trace in entirety; and
the first and second patterns comprise mirror image areas at least where the circuit trace is defined.

15. The web of claim 14 wherein the first and second metal foil layers are of equal thickness.

16. The web of claim 10 wherein:
the circuit trace is a main range circuit; and
the first pattern further defines a tweeter circuit trace.

17. A metal-containing web for use in a liquid-based etch process to make an electronic circuitry surveillance device, the electronic circuitry surveillance device having at least one circuit trace having at least one inductor functional area and at least first and second charge storage functional areas, comprising:
an elongated substrate having first and second opposing surfaces;
a first metal foil layer disposed upon the first surface of the substrate;
a first etch-resistant layer disposed upon the first metal foil layer, the first etch-resistant layer having a first pattern defining at least the inductor functional area and the first charge storage functional area;
a second metal foil layer disposed upon the second surface of the substrate; and
a second etch-resistant layer disposed upon the second metal foil layer in register with the first etch-resistant layer, the second etch-resistant layer having a second pattern defining at least the inductor functional area and the second charge storage functional area.

18. The web of claim 17 wherein the first and second patterns comprise mirror image areas at least where the inductor functional area is defined.

19. The web of claim 17 wherein the first and second metal foil layers are of equal thickness.

20. The web of claim 10 wherein the first pattern further defines a fusible link functional area.

21. A planar speaker diaphragm comprising:
a substrate having first and second opposing surfaces; and
at least one circuit trace, the circuit trace having a first metal-containing part disposed upon the first surface of the substrate and a second metal-containing part disposed upon the second surface of the substrate in a substantially opposing relationship.

22. The planar speaker diaphragm of claim 21 wherein time circuit trace terminates at each end thereof in a respective bonding pad.

23. An electronic circuitry surveillance product comprising:
a substrate having first and second opposing surfaces;
an inductor trace, the inductor trace having a first metal-containing part disposed upon the first surface of the substrate and a second metal-containing part disposed upon the second surface of the substrate in a substantially opposing relationship;
a first charge storage patch disposed upon the first surface of the substrate and coupled to the inductor trace;
a variable impedance element disposed upon the second surface of the substrate and having a first end and a second end, the first end of the variable impedance element being coupled to the inductor trace; and
a second charge storage patch disposed upon the second surface of the substrate and coupled to the second end of the variable impedance element.

24. The electronic circuitry surveillance product of claim 23 wherein the variable impedance element comprises a fuse trace.

25-31. (canceled)

32. A metal trace having a thickness, comprising:
a first portion of the thickness of the metal separated from a second portion of the thickness of the metal by a substrate, and
a conductive path by which the first portion and the second portion are in electrical communication.

33. The metal trace of claim 32, wherein the first portion is substantially in register with the second portion.

34. The metal trace of claim 32, wherein the first portion and the second portion are substantially equal in thickness.

35. The metal trace of claim 32, wherein the first portion and the second portion are not substantially equal in thickness.

36. The metal trace of claim 32, wherein the first portion and the second portion extend from an edge of the substrate, and the conductive path comprises a crimp, a bond, an electrically conductive adhesive bond, or any combination thereof between the first portion and the second portion extending from the edge of the substrate.

37. The metal trace of claim 32, wherein the conductive path comprises a conductive strip or clip in communication with the first portion and the second portion.

38. The metal trace of claim 32, wherein the conductive path comprises a via in the substrate, the via having disposed therein a conductive material in communication with the first portion and the second portion.

39. A high fidelity, electrically continuous liquid-etched metal trace comprising a thickness defined by sidewalls and apportioned to opposing sides of a substrate, wherein the sidewalls are substantially linear in shape.

40. An electrically continuous liquid-etched metal trace having a thickness apportioned to opposing sides of a substrate.
